(19) United States
(12) Patent Application Publication
(10) Pub. No.: US 2015/0213894 A1
(43) Pub. Date: Jul. 30, 2015

(54) SEMICONDUCTOR DEVICE

(71) Applicant: Kohei Oikawa, Kawasaki-shi (JP)

(72) Inventor: Kohei Oikawa, Kawasaki-shi (JP)

(73) Assignee: KABUSHIKI KAISHA TOSHIBA, Minato-ku, Tokyo (JP)

(21) Appl. No.: 14/374,651

(22) PCT Filed: Aug. 29, 2012
(86) PCT No.: PCT/JP2012/072527

§ 371 Date: Jul. 25, 2014

(30) Foreign Application Priority Data
Jan. 26, 2012 (JP) 2012-014015

(51) Int. Cl. G11C 16/08; G11C 5/06; G11C 16/04; G11C 16/24; G11C 5/02

(52) U.S. Cl. CPC G11C 16/08; G11C 16/24; G11C 5/02; G11C 16/0483; G11C 5/063

(57) ABSTRACT

A semiconductor includes first and second cell blocks, a first word line, a logic circuit, and a control circuit. The first cell block is coupled between a first terminal and a second terminal. The second cell block is coupled between a third terminal and a fourth terminal. The first word line is coupled to a first memory cell in the first cell block and a second memory cell in the second cell block. The logic circuit is coupled to the second and fourth terminals. The control circuit is configured to control a voltage applied to the first word line to cause the first cell block and the second cell block to output an output voltage which is based on data stored in the first and second memory cells.

### CROSS-REFERENCE TO RELATED APPLICATIONS

This application is based upon and claims the benefit of priority from Japanese Patent Application No. 2012-014015, filed Jan. 26, 2012, the entire contents of which are incorporated herein by reference.

### FIELD

Embodiments described herein relate generally to a semiconductor device.

### BACKGROUND

Field-programmable gate arrays (FPGAs) are utilized for various apparatuses and are widely prevalent.

### BRIEF DESCRIPTION OF THE DRAWINGS

FIG. 1 is a block diagram of a semiconductor device according to a first embodiment;

FIG. 2 is a circuit diagram of a memory module and a logic circuit module according to the first embodiment;

FIG. 3 and FIG. 4 are timing charts of various signals for a semiconductor device according to the first embodiment;

FIG. 5 is a circuit diagram of a memory module and a logic circuit module according to a second embodiment;

FIG. 6 is a timing chart of various signals for a semiconductor device according to the second embodiment;

FIG. 7 is a circuit diagram of a memory module and a logic circuit module according to a third embodiment;

FIG. 8 is a timing chart of various signals for a semiconductor device according to the third embodiment;

FIG. 9 is a perspective view of a memory module according to a fourth embodiment;

FIG. 10 is a cross-sectional view of the memory module according to the fourth embodiment; and

FIG. 11 is a circuit diagram of a memory module and a logic circuit module according to a fifth embodiment.

### DETAILED DESCRIPTION

In general, according to one embodiment, a semiconductor includes: a first cell block; a second cell block; a first word line; a logic circuit; and a control circuit. The first cell block is coupled between a first terminal and a second terminal and includes a plurality of memory cells coupled in series. The second cell block is coupled between a third terminal and a fourth terminal and includes a plurality of memory cells coupled in series. The first word line is coupled to a first memory cell and a second memory cell. The first memory cell is an n-th memory cell from the first terminal in the first cell block. The second memory cell is an n-th memory cell from the third terminal in the second cell block. The logic circuit is coupled to the second terminal and the fourth terminal. The control circuit is configured to control a voltage applied to the first word line to output, to the logic circuit, an output voltage which is based on data stored in the first memory cell and the second memory cell.

### First Embodiment

A semiconductor device according to a first embodiment will be described.

### 1. Configuration of the Semiconductor Device

### 1.1 Overall Configuration of the Semiconductor Device

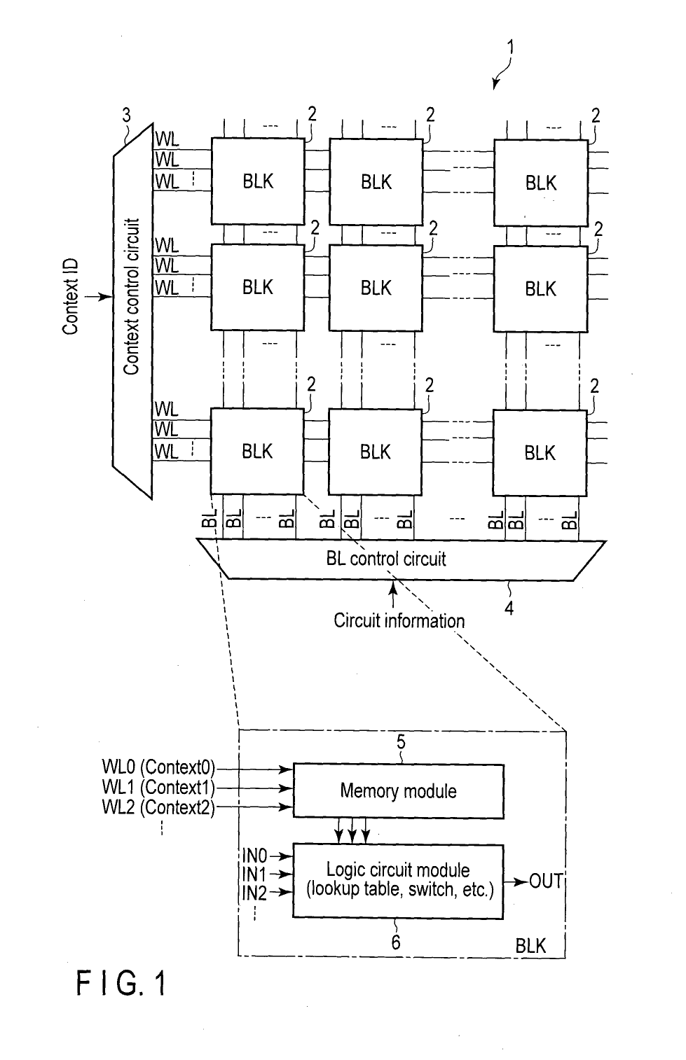

First, a configuration of the semiconductor device according to the present embodiment will be described. FIG. 1 is a block diagram of an FPGA according to the present embodiment.

As shown in FIG. 1, an FPGA 1 includes a plurality of blocks 2, a context control circuit 3, and a bit-line control circuit 4.

Each of the blocks 2 includes a memory module 5 and a logic circuit module 6. The memory module 5 holds logic circuit information (configuration information or context information) on logic circuits that are to be implemented in the logic circuit module 6. The logic circuit module 6 includes various logic circuits. More specifically, the logic circuit module 6 includes a lookup table and/or a plurality of switches. The logic circuit modules 6 of some of the blocks 2 include a lookup table, and the logic circuit modules 6 of other blocks 2 include switches. The lookup tables and switches implement functions in accordance with context information. In response to an input signal IN, the logic circuit module 6 carries out a predetermined calculation to output an output signal OUT.

The context control circuit 3 receives an external context ID. The context control circuit 3 decodes the context ID and selects context information in accordance with the result of the decoding. Thus, the selected context information is supplied to the logic circuit module 6 from the memory module 5. Furthermore, the context control circuit 3 writes the context information to the memory module 5 by application of an appropriate voltage.

The bit-line control circuit 4 supplies a required voltage to the memory module 5. For example, when writing context information to the memory module 5, the bit-line control circuit 4 externally receives circuit information and applies the corresponding voltage to the memory module 5.

### 1.2 Configuration of the Block 2

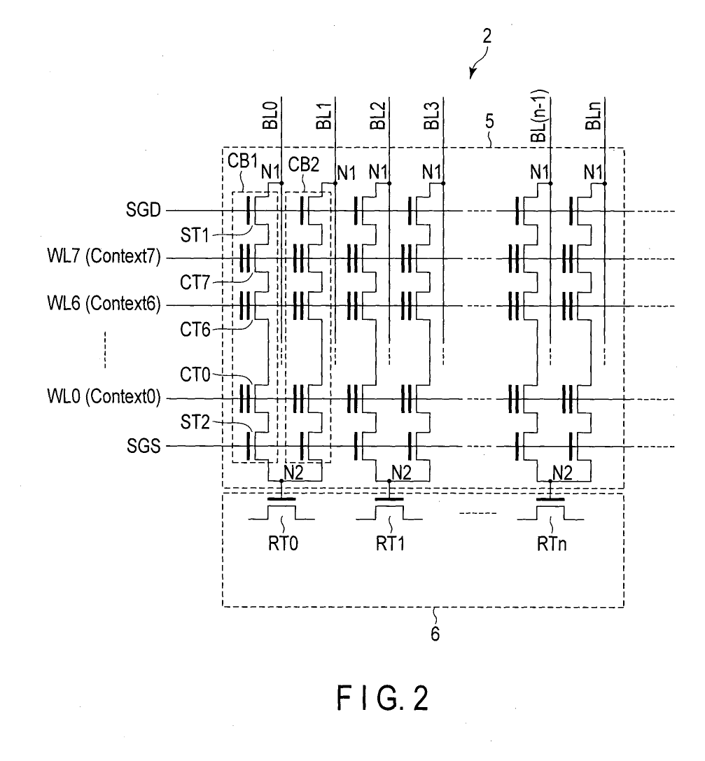

A configuration of the block 2 will be described in detail with reference to FIG. 2. FIG. 2 is a circuit diagram of the block 2.

First, the memory module 5 will be described. As shown in FIG. 2, the memory module includes a plurality of cell blocks CB. Each of the cell blocks CB includes select transistors ST1 and ST2 and a plurality of memory cell transistors CT (CT0 to CT7). The present example involves eight memory cell transistors CT. However, the cell blocks are not limited to this configuration and may involve 16 or 32 memory cell transistors CT. The memory cell transistor CT is a MOS transistor including a stacked gate with a charge accumulation layer and a control gate. The memory cell transistor CT holds context information on the logic circuit module 6. The memory cell transistor CT may be a floating gate transistor that uses a conductive film as the charge accumulation layer or a metal-oxide-nitride-oxide-silicon (MONOS) structure or a silicon-oxide-nitride-oxide-silicon (SONOS) structure which uses an insulating film as the charge accumulation layer. The memory cell transistor CT can hold one bit data by being set to a high threshold state or a low threshold state depending on whether charge is injected into the charge accumulation layer. Of course, one memory cell transistor CT may hold more than one bit data by enabling the threshold to set to more than two states. The memory cell transistors CT are connected in series between the source of select transistor ST1 and the drain of select transistor ST2. The drain of select transistor ST1 is connected to a bit line BL (BL0 to BLn, n being a natural number of at least two). This connection node is referred to as a node N1.

A cell block CB connected to an even-numbered bit line BLi (i=0, 2, 4, . . . , (n−1)) is hereinafter referred as a first cell block CB1. A cell block CB connected to an odd-numbered bit line BL (i+1) is hereinafter referred as a second cell block CB2. However, the cell block is simply referred to as cell block CB if the first and second cell blocks are not distinguished from each other.

The source of select transistor ST2 in the first cell block CB1 connected to a certain bit line BLi is connected to the source of select transistor ST2 in the second cell block CB2 connected with the bit line BL (i+1) adjacent to bit line BLi, into a connection node referred to as a node N2. The two cell blocks CB1 and CB2 connected in common to node N2 hold complementary data. That is, one-bit cell block information is written to the memory module 5 using two memory cell transistors CT connected to the same word line WL in the first cell block CB1 and second cell block CB2. More specifically, when “1” data is written to one of the two memory cell transistors CT, “0” data is written to the other memory cell transistor CT. That is, when certain data is written to one of the memory cell transistors CT, data obtained by inverting the certain data is written to the other memory cell transistor CT. Furthermore, the bit line BL connects the blocks BLK arranged in the same column in the FPGA together. Then, the bit-line control circuit 4 provides a voltage to the bit line BL.

Control gates of the memory cell transistors in the same row are connected in common to the same word line WL (WL0 to WL7). Furthermore, gates of select transistors ST1 are connected in common to a select gate line SGD. Gates of select transistors ST2 are connected in common to a select gate line SGS. The word lines WL and select gate lines SGD and SGS each connect the blocks BLK arranged in the same row in the FPGA together. The context control circuit 3 applies a voltage to the word lines WL and select gate lines SGD and SGS. For example, when Context0 is selected as the result of decoding of a context ID, the context control circuit 3 selects word line WL0 and applies the required voltage to word line WL0.

The logic circuit module 6 will be described. The logic circuit module 6 includes a lookup table or switches as described above. The logic circuit module 6 further includes a MOS transistor PT (PT0 to PTn) provided for each node N2. The gate of each MOS transistor PT is connected to node N2 associated with the MOS transistor MT. The source and drain of the MOS transistor are connected to the lookup table or the switches. The logic circuit module 6 is configurable by turning on or off the MOS transistors PT depending on the potential of node N2. According to the present embodiment, the MOS transistor PT is a circuit controlled by node N2. However, node N2 may control another circuit such as an inverter, a NAND gate, or a latch circuit.

### 2. Operation of the Semiconductor Device

An operation of the FPGA 1 according to the present embodiment will be described.

### 2.1 Operation of Writing Context Information

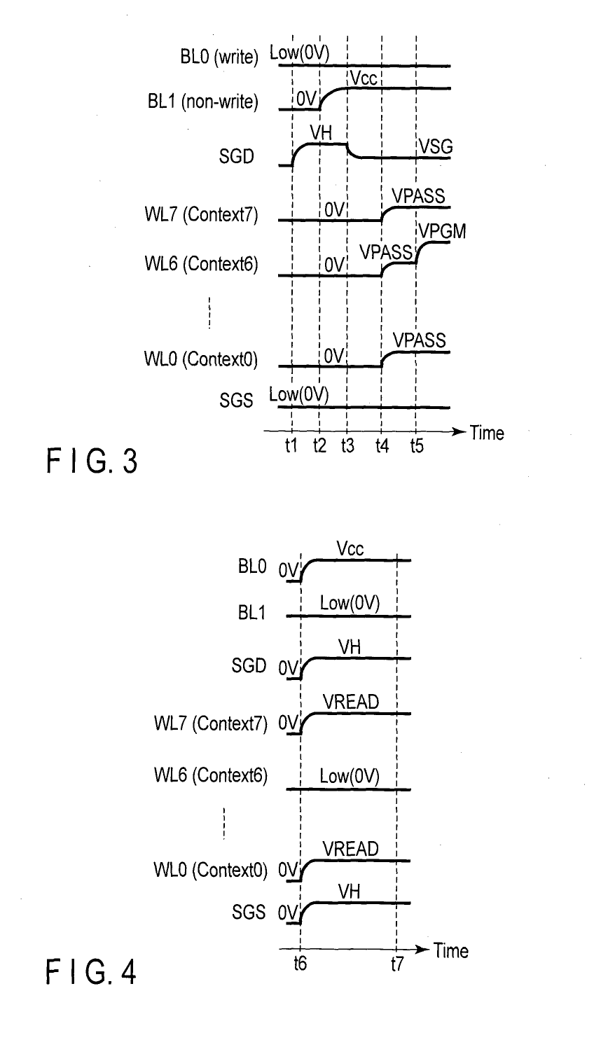

First, an operation of writing context information to the memory module 5 will be described. The following description uses FIG. 3 and takes, as an example, write to memory cell transistor CT6 connected to bit line BL0 and word line WL6. FIG. 3 is a timing chart showing a change in the voltage of each interconnect.

First, at time t1, the bit-line control circuit 4 makes bit line BL0 and complementary bit line BL1 low (0 V). Furthermore, the context control circuit 3 makes select gate line SGD high (voltage VH) to turn on select transistor ST1. All word lines WL0 to WL7 and the select gate line SGS are at 0 V.

Then, at time t2, the bit-line control circuit 4 sets the potential of bit line BL1 to Vcc. Potential Vcc is transferred to a channel of the memory cell transistor CT in the second cell block CB2.

Subsequently, at time t3, the context control circuit 3 reduces the potential of select gate line SGD from VH to VSG. Potential VSG is such that 0 V is allowed to pass though select transistor ST1, whereas Vcc is prevented from passing through select transistor ST1. Thus, select transistor ST1 in the first cell block CB1 is kept on, but select transistor ST1 in the second cell block CB2 is cut off. Therefore, potential the channel of the memory cell transistor CT in the second cell block CB2 is set to a floating state at Vcc.

Then, at time t4, the context control circuit 3 applies a voltage VPASS to all word lines WL0 to WL7. VPASS denotes a voltage that turns on the memory cell transistor CT regardless of the data held in the memory cell transistor CT. Subsequently, at time t5, the context control circuit 3 applies a program voltage VPGM (>VPASS) to selected word line WL6.

As a result, in memory cell transistor CT6 connected to bit line BL0 and word line WL6, the potential of the channel is 0 V and the potential of the control gate is VPGM. Thus, charge is injected into the charge accumulation layer to write the corresponding data to this memory cell transistor CT6. On the other hand, in memory cell transistor CT6 connected to bit line BL1 and word line WL6, the potential of the channel is set almost the same as the potential of the control gate by coupling with the word line WL. Consequently, no charge is injected into the charge accumulation layer, and no data is written to this memory cell transistor CT6. In other words, data complementary to the data written to memory cell transistor CT6 connected to bit line BL0 and word line WL6 is written to memory cell transistor CT6 connected to bit line BL1 and word line WL6.

In this manner, data is written in common to all of the plurality of memory cell transistors CT connected to the word line WL, at a time. For example, Context0 to Context7 are written to word lines WL0 to WL7.

### 2.2 Operation of the Logic Circuit

An operation of the FPGA 1 based on context information will be described focusing particularly on the memory module 5. The operation will be described with reference to FIG. 4 taking, as an example, a case where context information is read from memory cell transistors CT6 connected to bit lines BL0 and BL1 and to word line WL6. FIG. 4 is a timing chart showing a voltage of each interconnect.

First, the bit-line control circuit 4 makes bit line BL0 and complementary bit line BL1 low (0 V). Furthermore, the context control circuit 3 sets all word lines WL0 to WL7 and select gate lines SGD and SGS to 0 V.

Then, at time t6, the bit-line control circuit 4 sets the potential of bit line BL0 to Vcc. The potential of bit line BL1 is kept at 0 V. Moreover, at time t6, the context control circuit 3 sets the potentials of select gate lines SGD and SGS to VH to turn select transistors ST1 and ST2 on. Furthermore, the context control circuit 3 applies a voltage VREAD to unselected word lines WL0 to WL5 and WL7, while applying 0 V to selected word line WL6. VREAD is a voltage that turns on the memory cell transistor CT regardless of the data held in the memory cell transistor CT. In the case described herein, the voltage of 0 V is applied to the selected word line. However, the voltage is not limited to 0 V. The voltage applied to the selected word line may be, for example, at least lower than the voltage applied to the unselected word lines.

As a result, when memory cell transistor CT6 of the first cell block CB1 is turned on, the voltage Vcc is transferred from the bit line BL via node N2 to the gate of MOS transistor PT0 to turn on MOS transistor PT0. On the other hand, when memory cell transistor CT6 of the first cell block CB1 is turned off, memory cell transistor CT6 in the first cell block CB1 should have been turned on (because the two memory cell transistors CT6 can hold complementary data). Thus, 0 V is transferred to the gate of MOS transistor PT0 to turn off MOS transistor PT0.

In this manner, configuration information in the memory module 5 controls the operation of MOS transistor PT0. The logic circuit module 6 implements the appropriate function by selecting any appropriate word line WL. Data is read at a time from the plurality of memory cell transistors CT connected the same word line. Thus, selection of, for example, word line WL6 causes Context6 to be read, allowing the corresponding voltage to be applied to the gates of MOS transistors PT0 to PTn.

The logic circuit module 6 is configured to implement various functions in a time sharing manner. That is, when word line WL0 is selected to allow Context0 to be read, the logic circuit module 6 implements a function corresponding to Context0. Then, when word line WL1 is selected to allow Context1 to be read, the logic circuit module 6 implements a function corresponding to Context1.

### 3. Effects According to the Present Embodiment

As described above, the configuration according to the present embodiment allows the degree of integration of the FPGA to be increased. This effect will be described below.

With miniaturization and improved performance for a semiconductor process, the FPGA has started to be applied even to the field in which custom design LSIs are conventionally utilized. However, there is a several tens of times difference between the FPGA and the custom design in the area required to implement the same function. Hence, an increase in the degree of integration of the FPGA is an important challenge.

For the FPGA, a scheme called multi-context FPGA is known. The multi-context FPGA provides a configuration memory (SRAM) that holds circuit information on the FPGA. The scheme divides the circuit information into a plurality of contexts and utilizes the logic circuit module except for the configuration memory in a time sharing manner. This offers the possibility of reducing the area of the FPGA. However, the division into contexts tends to increase the total amount of configuration information. As a result, the area of SRAM that stores the configuration information is increased, thus precluding the area of the FPGA from being sufficiently reduced.

In this regard, in the configuration according to the present embodiment, the configuration memory (memory module 5) includes a NAND flash memory, and the contexts are assigned to the respective word lines WL. Operation is performed with the selected word line switched so that the logic circuit module 6 can implement the required function. This enables higher density of the configuration memory of the multi-context FPGA. As a result, even with an increased number of contexts, an increase in the area of the multi-context FPGA can be minimized.

### Second Embodiment

A semiconductor device according to a second embodiment will be described. The present embodiment is the first embodiment in which the MOS transistor PT is replaced with a latch circuit. Only differences from the first embodiment will be described below.

### 1. Configuration of the Semiconductor Device

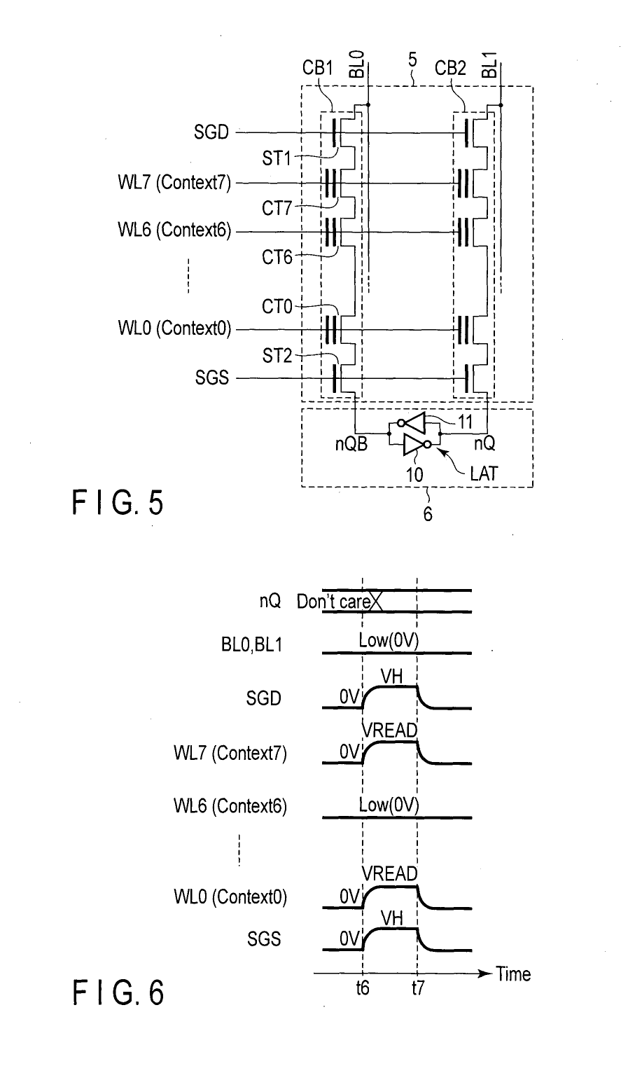

FIG. 5 is a circuit diagram of a partial area of the block 2 according to the present embodiment, and particularly shows a set of the first and second cell blocks CB1 and CB2 and the corresponding logic circuit module 6.

As shown in FIG. 5, the configuration according to the present embodiment corresponds to the first embodiment modified as follows.

(1) The logic circuit module 6 includes a latch circuit LAT instead of the MOS transistor PT. The latch circuit LAT includes an inverter 10 with an input node connected to a node nQB and an output node connected to a node nQ and an inverter 11 with an input node connected to node nQ and an output node connected to node nQB. Nodes nQB and nQ are further connected to logic circuits (a lookup table or switches; not shown in the drawings).

(2) The source of select transistor ST2 in the first cell block CB1 is connected to the input (in the present example, node nQB) of the latch circuit LAT. The source of select transistor ST2 in the second cell block CB2 is connected to the output (in the present example, node nQ) of the latch circuit LAT. The sources of the two select transistors 2 are not directly connected together.

### 2. Operation of the Semiconductor Device

An operation of the FPGA 1 according to the present embodiment will be described. An operation of writing context information to the memory module 5 is similar to that according to the first embodiment.

An operation will be described which is performed by the FPGA 1 in implementing a certain function based on the configuration information in the memory module 5. The following description uses FIG. 6 and takes, as an example, a case where context information is read from memory cell transistor CT6 connected to bit lines BL0 and BL1 and word line WL6. FIG. 6 is a timing chart showing a variation in the voltage of each interconnect.

First, the bit-line control circuit 4 makes bit line BL0 and complementary bit line BL1 low. Furthermore, the context control circuit 3 sets all word lines WL0 to WL7 and select gate lines SGD and SGS to 0 V.

Then, at time t6, the potentials of select gate lines SGD and SGS are set to VH to turn select transistors ST1 and ST2 on. Moreover, the context control circuit 3 applies the voltage VREAD to unselected word lines WL0 to WL5 and WL7, while applying 0 V to selected word line WL6.

As a result, when memory cell transistor CT6 in the first cell block CB1 is turned on, 0 V is transferred to node nQB to make node nQB low, while making node nQ high. On the other hand, when memory cell transistor CT6 in the first cell block CB1 is turned off, memory cell transistor CT6 in the second cell block CB2 is turned on. Thus, the voltage of 0 V is transferred to node nQ to make node nQ low, while making node nQB high.

After the state of the latch circuit LAT is established as described above, the context control circuit 3 sets all word lines WL0 to WL7 and select gate lines SGD and SGS to 0 V at time t7. Thus, at least select transistors ST1 and ST2 are turned off to prevent current from flowing through the bit line BL.

Also in the present example, as is the case with the first embodiment, data is read at a time from a plurality of memory cell transistors CT connected to the same word line. Thus, the states of n latch circuits LAT are determined by the read context information.

### 3. Effects According to the Present Embodiment

The configuration according to the present embodiment reads the context information from the memory module 5, into the latch circuit LAT, where the context information is held. Thus, while the logic circuit module 6 is in operation, the memory module 5 need not operate. That is, the word lines WL and select gate lines SGD and SGS can all be made low (that is, can be negated). This prevents leakage current from flowing through the memory cell transistor CT, enabling a reduction in the energy consumption of the FPGA.

Moreover, a voltage needs to be applied to the word line WL only when context information is read from the memory module 5 into the latch. That is, the time can be reduced for which a high voltage is applied to the memory cell transistor CT. This enables a variation in the threshold for the memory cell transistor CT to be suppressed which results from uselessly trapping or emission of charge in or from the charge accumulation layer.

### Third Embodiment

A semiconductor device according to a third embodiment will be described. The present embodiment corresponds to the above-described second embodiment in which context information is stored at a rate of one cell per bit instead of two cells per bit. Only differences from the second embodiment will be described below.

### 1. Configuration of the Semiconductor Device

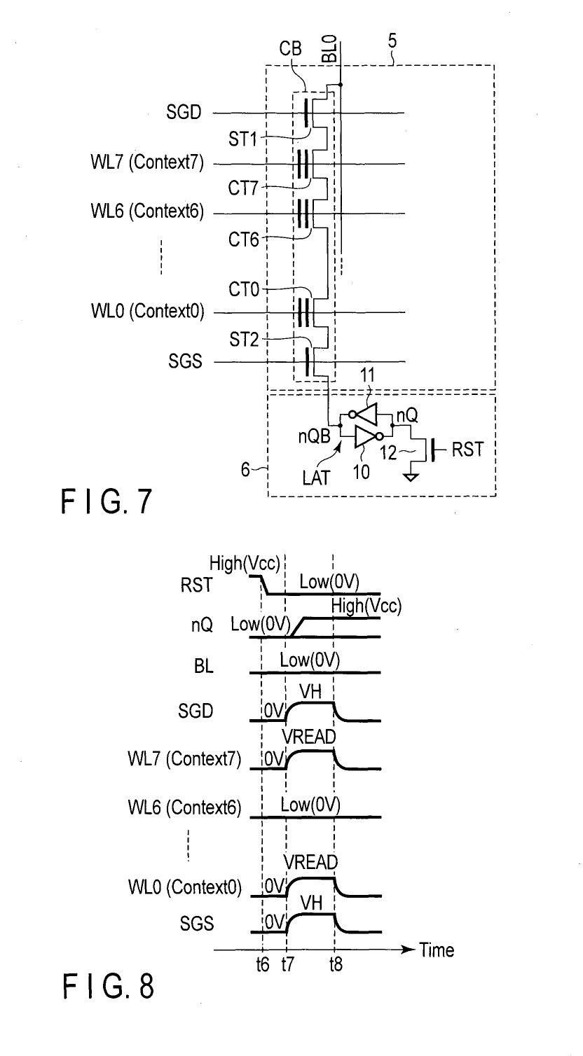

FIG. 7 is a circuit diagram of a partial area of the block 2 according to the present embodiment. FIG. 7 particularly shows a configuration of one CB cell block and the corresponding logic circuit module 6.

As shown in FIG. 7, the configuration according to the present embodiment corresponds to the second embodiment modified as follows.

(1) One latch circuit LAT is provided for each cell block. The source of select transistor ST2 is connected to node nQB of the latch circuit LAT which is associated with select transistor ST2.

(2) The logic circuit module 6 includes a reset circuit. The reset circuit is configured to reset the latch circuit LAT and includes, for example, a MOS transistor 12. The drain of the MOS transistor 12 is connected to node nQ. The source of the MOS transistor 12 is grounded. The gate of the MOS transistor 12 is provided with a signal RST. Signal RST is provided by, for example, the context control circuit 3.

### 2. Operation of the Semiconductor Device

An operation of the FPGA 1 according to the present embodiment will be described. An operation of writing context information to the memory module 5 is similar to that according to the first embodiment. The following description uses FIG. 8 and takes, as an example, a case where content information is read from memory cell transistor CT6 connected to bit line BL0 and word line WL6 when the logic circuit module 6 operates in accordance with the context information. FIG. 8 is a timing chart showing a variation in the voltage of each interconnect.

First, the latch circuit LAT is reset. That is, the context control circuit 3 makes signal RST high. Thus, the MOS transistor 12 is turned on to make node nQ low, while making node nQB high.

Thereafter, at time t7, the context control circuit 3 makes signal RST low. Thus, the MOS transistor 12 is turned off.

Then, at time t7, the bit-line control circuit 4 makes the bit line BL low. Furthermore, the context control circuit 3 sets the potentials of select gate lines SGD and SGS to VH to turn select transistors ST1 and ST2 on. Moreover, the context control circuit 3 applies the voltage VREAD to unselected word lines WL0 to WL5 and WL7, while applying 0 V to selected word line WL6.

As a result, when memory cell transistor CT6 is turned on, 0 V is transferred to node nQB to reverse the data in the latch circuit LAT. That is, node nQB is made high, while node nQ is made low. On the other hand, when memory cell transistor CT6 is tuned off, the data in the latch LAT remains unchanged.

Thereafter, at time t8, the context control circuit 3 sets all word lines WL0 to WL8 and select gate lines SGD and SGS to 0 V. Thus, at least select transistors ST1 and ST2 are turned off to prevent current from flowing through the bit line BL.

### 3. Effects According to the Present Embodiment

Even the configuration according to the present embodiment has effects similar to the effects of the second embodiment. Moreover, the present embodiment reduces the number of memory cell transistors required for one context to half. Thus, the area of the FPGA can be significantly reduced.

### Fourth Embodiment

A semiconductor device according to a fourth embodiment will be described. The present embodiment relates to a specific configuration of the memory module 5 according to the first to third embodiments. The memory module 5 according to the present embodiment is a NAND flash memory in which memory cell transistors CT are three-dimensionally stacked.

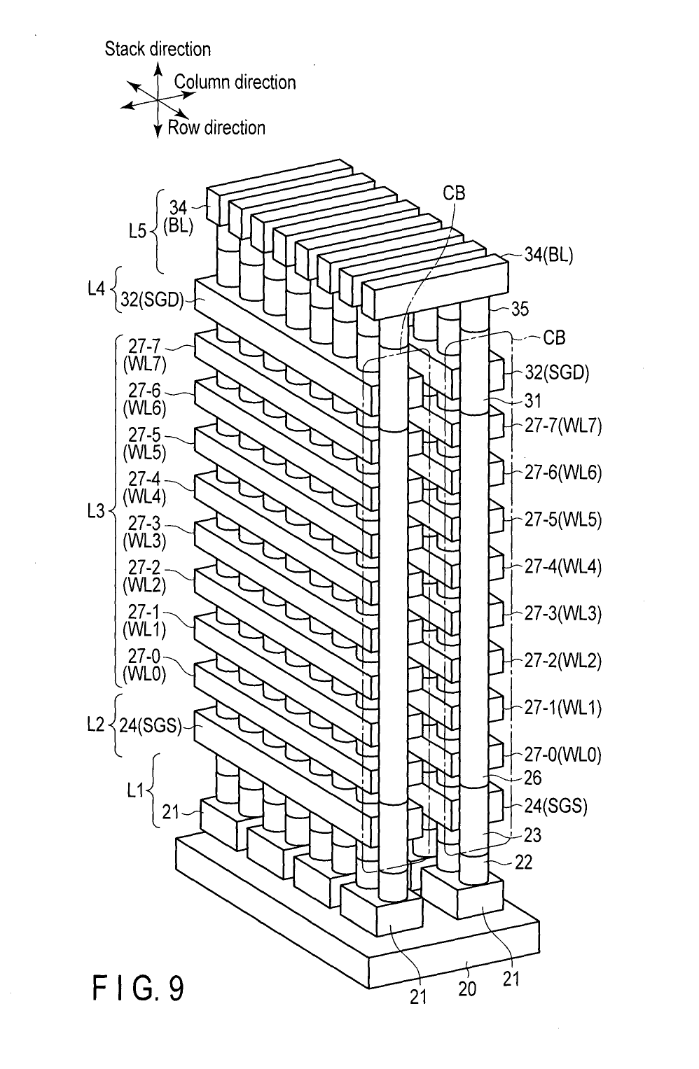

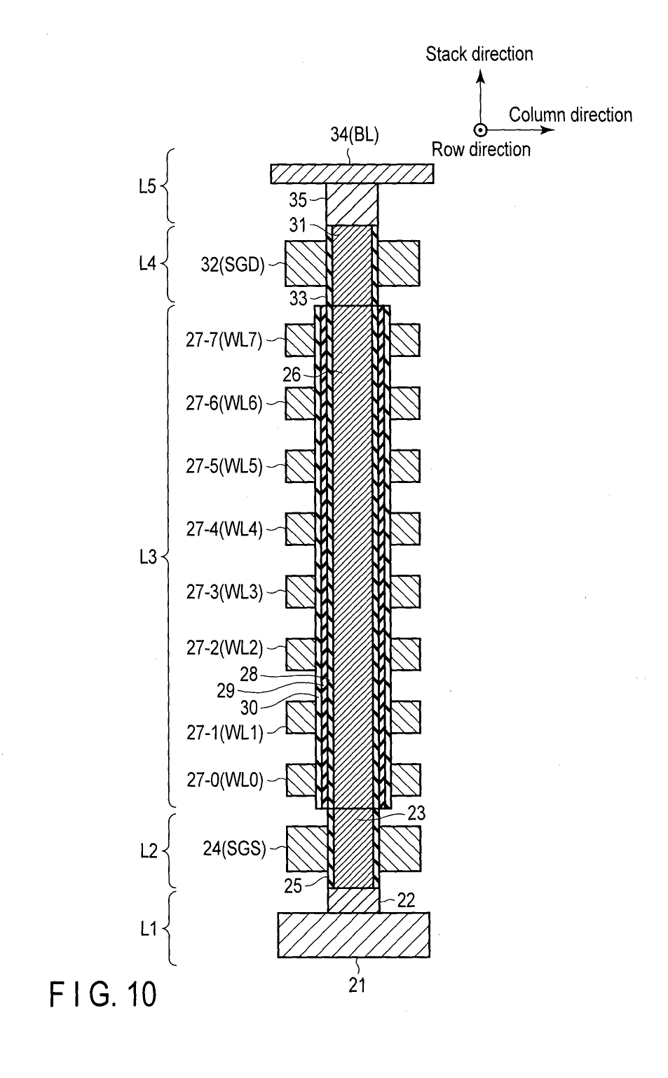

FIG. 9 and FIG. 10 are a perspective view and a cross-sectional view of the memory module 5. As shown in FIG. 9 and FIG. 10, the memory module 5 is formed above a semiconductor substrate 20. The memory module 5 includes an interconnect layer L1, a select transistor layer L2, a memory cell transistor layer L3, a select transistor layer L4, and an interconnect layer L5 which are sequentially formed above the semiconductor substrate 20.

Source lines are formed in the interconnect layer L1. Select transistors ST2 are formed in select transistor layer L2. Memory cell transistors CT0 to CT7 are formed in the memory cell transistor layer L3. Select transistors ST1 are formed in select transistor layer L3. Bit lines BL are formed in the interconnect layer L5.

The interconnect layer L1 includes source layers 21 and plug layers 22. The plug layers 22 are formed on each of the source line layers 21 so as to extend perpendicularly to the surface of the semiconductor substrate 20. The source line layers 21 and the plug layers 22 are formed of metal, for example, tungsten (W). The source line layers 21 correspond to, for example, nodes N2 in FIG. 2.

Select transistor layer L2 includes conductive layers 23 and 24 and gate insulating films 25. Each of conductive layers 23 is formed on the corresponding plug layer 22 like a pillar shape. Furthermore, each of conductive layers 24 is formed so as to surround the periphery of conductive layer 23 via the corresponding gate insulating film 25. Moreover, conductive layers 24 are formed like stripes along a row direction so that one conductive layer 24 covers a plurality of conductive layers 23. Each of conductive layers 24 functions as a select gate line SGS. Conductive layer 24, the gate insulating film 26, and conductive layer 23 form a select transistor ST2. Conductive layers 23 and 24 are formed of, for example, polycrystalline silicon. The gate insulating film 25 is formed of a silicon oxide film (SiO₂).

The memory cell transistor layer L3 includes conductive layers 26, word-line conductive layers 27-0 to 27-7, gate insulating films 28, charge accumulation layers 29, and block layers 30. Each of conductive layers 26 is formed on corresponding conductive layer 23 like a pillar shape. Each of the gate insulating films 28 is formed so as to surround the periphery of corresponding conductive layer 26. Each of the charge accumulation layers 29 is formed so as to surround the periphery of the corresponding gate insulating film 28. Each of the block layers 30 is formed so as to surround the periphery of the corresponding charge accumulation layer 29. The word-line conductive layers 27-0 to 27-7 are stacked on one another via interlayer insulating films (not shown in the drawings) and are formed so as to surround the periphery of the block layer 30. The word-line conductive layers 27-0 to 27-7 are formed along the row direction similarly to conductive layer 24 so that one word-line conductive layer 27 covers a plurality of conductive layers 26. The word-line conductive layers 27-0 to 27-7 function as word lines WL0 to WL7 (control gates). The gate insulating film 28 and the block layer 30 are formed of, for example, a silicon oxide (SiO₂) film. The charge accumulation layer is formed of a silicon nitride (SiN) film. Furthermore, conductive layers 26 and 27 are formed using, for example, a polycrystalline silicon layer. The word-line conductive layers 27-0 to 27-7, the gate insulating films 28, the charge accumulation layers 29, the block layers 30, and conductive layers 26 form MONOS memory cell transistors CT0 to CT7. The gate insulating film 28, the charge accumulation layer 29, and the block layer 30 are not separated into pieces for the respective memory cell transistors CT, and are formed, for example, all over a side surface of conductive layer 26.

Select transistor layer L4 includes conductive layers 31 and 32 and gate insulating films 33. Each of conductive layers 31 is formed on the corresponding plug layer 22 like a pillar shape. Furthermore, each of conductive layers 32 is formed so as to surround the periphery of conductive layer 31 via the corresponding gate insulating film 33. Moreover, conductive layers 32 are formed along the row direction so that one conductive layer 32 covers a plurality of conductive layers 31. Each of conductive layers 32 functions as a select gate line SGD. Conductive layer 32, the gate insulating film 33, and conductive layer 31 form a select transistor ST1. Conductive layers 31 and 32 are formed of, for example, polycrystalline silicon. The gate insulating film 33 is formed of a silicon oxide (SiO₂) film.

The interconnect layer L5 includes bit-line layers 34 and plug layers 35. Each of the plug layers 35 is formed on corresponding conductive layer 31 like a column. The bit-line layers 34 are formed like stripes along a column direction and function as bit lines BL. The bit-line layers 34 and the plug layers 35 are formed of metal, for example, tungsten (W). Each of the bit-line layers 34 is connected in common to a plurality of cell blocks CB.

As described above, the memory cell section 5 may have the structure in which the memory cell transistors CT are stacked perpendicularly to the semiconductor substrate. The configuration in FIG. 9 corresponds to FIG. 2, and thus the source line 21 connects two cell blocks CB together. However, in the configuration corresponding to FIG. 5 and FIG. 7, the source line 21 from each cell block CB is connected independently to the logic circuit module 6.

### Fifth Embodiment

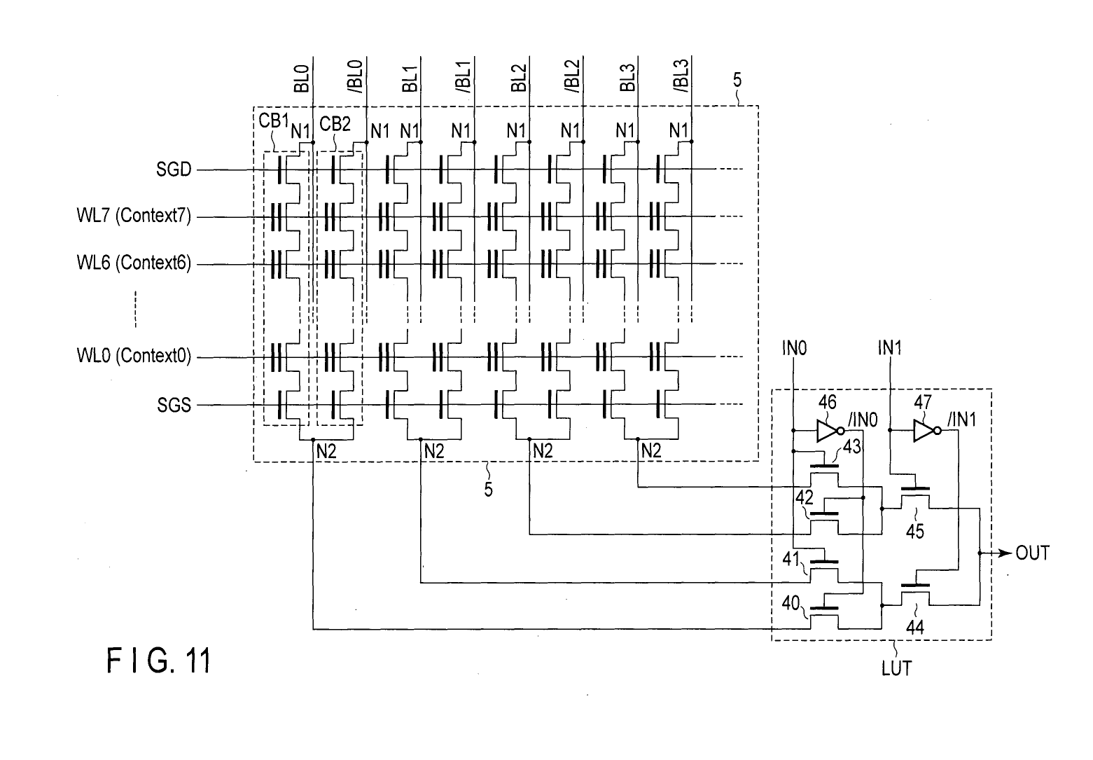

A semiconductor device according to a fifth embodiment will be described. The present embodiment relates to a specific example of the lookup table described in the first embodiment. FIG. 11 is a circuit diagram of the memory module 5 and a lookup table LUT in the logic circuit module 6 according to the present embodiment.

As shown in FIG. 11, the memory module 5 has a configuration similar to the configuration in FIG. 2 described in the first embodiment. That is, the first cell block CB1 and the second cell block CB2 hold complementary data. In FIG. 11, bit lines connected to cell blocks holding complementary data are represented as a pair of bit lines (BL and /BL). For example, bit lines BL0 and /BL0 in FIG. 11 correspond to the bit lines BL0 and BL1 in FIG. 2. Bit lines BL1 and /BL1 correspond to the bit lines BL2 and BL3 in FIG. 2.

The lookup table LUT includes n-channel MOS transistors 40 to 45 and inverters 46 and 47. The inverter 46 inverts an input signal IN0 and outputs a signal /IN0. The inverter 47 inverts an input signal IN1 and outputs a signal /IN1.

The transistor 40 includes a current path connected, at one end thereof, to a node N2 of a cell block connected to the pair of bit lines BL0 and /BL0, and the signal /IN0 is input to a gate of the transistor 40. The transistor 41 includes a current path connected, at one end thereof, to a node N2 of a cell block connected to the pair of bit lines BL1 and /BL1, and the signal IN0 is input is input to a gate of the transistor 41. The transistor 42 includes a current path connected, at one end thereof, to a node N2 of a cell block connected to the pair of bit lines BL2 and /BL2, and the signal /IN0 is input to a gate of the transistor 42. The transistor 43 includes a current path connected, at one end thereof, to a node N2 of a cell block connected to the pair of bit lines BL3 and /BL3, and the signal IN0 is input to a gate of the transistor 43. The transistor 44 includes a current path connected, at one end thereof, to the other ends of the current paths of the transistors 40 and 41, and the signal /IN1 is input to a gate of the transistor 44. The transistor 45 includes a current path connected, at one end thereof, to the other ends of the current paths of the transistors 42 and 43, and the signal IN1 is input to a gate of the transistor 45. The other ends of the current paths of the transistors 44 and 45 are connected together so that a signal in this node is output as an output signal OUT.

The lookup table LUT configured as described above operates as a logic circuit with one output (OUT) for two inputs (IN0 and IN1). That is, the input signal IN0 turns the transistors 40 and 42 or the transistors 41 and 43 on. The input signal IN1 turns either of the transistors 44 and 45 on. The transistors 40 to 43 receive data corresponding to content information stored in a selected memory cell, from the memory module 5. Thus, the logic of the lookup table can be changed in a configurable manner. In other words, the one output (signal OUT) for the two inputs (signals IN0 and IN1) is changed by the signal provided by the memory module 5.

### MODIFICATION AND THE LIKE

As described above, the semiconductor device 1 includes: a first cell block (CB1 in FIG. 2); a second cell block (CB2 in FIG. 2); a first word line (one of WL in FIG. 2); a logic circuit (circuit 6 in FIG. 1); and a control circuit (controller 3 in FIG. 1). The first cell block is coupled between a first terminal (N1 of CB1 in FIG. 2) and a second terminal (N2 of CB1 in FIG. 2) and includes a plurality of memory cells coupled in series. The second cell block is coupled between a third terminal (N1 of CB2 in FIG. 2) and a fourth terminal (N2 of CB2 in FIG. 2) and includes a plurality of memory cells coupled in series. The first word line is coupled to a first memory cell and a second memory cell. The first memory cell is an n-th memory cell from the first terminal in the first cell block. The second memory cell is an n-th memory cell from the third terminal in the second cell block. The logic circuit is coupled to the second terminal (N2 of CB1 in FIG. 2) and the fourth terminal (N2 of CB2 in FIG. 2). The control circuit is configured to control a voltage applied to the first word line to cause the first cell block and the second cell block to output, to the logic circuit, an output voltage which is based on data stored in the first memory cell and the second memory cell.

The present configuration enables the degree of integration of the FPGA to be improved. The embodiments are not limited to those described above and may be modified in various manners. For example, in FIG. 2, the gates of the memory cell transistors CT in the same row are connected together. However, the gates of the memory cell transistors CT need not be connected together, and a gate interconnect may be provided for each memory cell transistor. However, the area of the memory module 5 can be reduced by connecting the gates of the memory cell transistors CT together as shown in FIG. 2.

Moreover, in FIG. 1, the word lines WL and the bit lines BL connect the plurality of blocks 2 together. However, also in this case, different interconnects may be provided for the respective blocks. However, the blocks are desirably connected together to reduce the area.

Furthermore, in FIG. 1, the control circuits 3 and 4 are shared by the plurality of blocks 2. Each of the control circuits 3 and 4 normally includes a circuit such as a voltage generation circuit which is large in area. Thus, the control devices 3 and 4 are desirably shared by the plurality of blocks 2. However, the control circuits 3 and 4 may be provided for each block. In this case, the plurality of blocks can operate in parallel. However, even in the configuration shown in FIG. 1, the blocks 2 in the same row can operate simultaneously.

Moreover, the description of the embodiments takes, as an example, the case where context information is selected by the context control circuit 3.

Furthermore, the fourth embodiment has been described taking, as an example, the case where the memory cell transistors CT are three-dimensionally stacked. However, the memory cell transistors CT may be two-dimensionally arranged on the semiconductor substrate.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a first cell block coupled between a first terminal and a second terminal and including a plurality of memory cells coupled in series;
a second cell block coupled between a third terminal and a fourth terminal and including a plurality of memory cells coupled in series;
a first word line coupled to a first memory cell and a second memory cell, the first memory cell being an n-th memory cell from the first terminal in the first cell block, the second memory cell being an n-th memory cell from the third terminal in the second cell block,
a logic circuit coupled to the second terminal and the fourth terminal; and
a control circuit configured to control a voltage applied to the first word line to cause the first cell block and the second cell block to output, to the logic circuit, an output voltage which is based on data stored in the first memory cell and the second memory cell.

2. The device according to claim 1, wherein the first memory cell and the second memory cell store complementary data each other.

3. The device according to claim 1, further comprising a second word line coupled to a third memory cell and a fourth memory cell, the third memory cell being an m-th memory cell from the first terminal in the first cell block, the fourth memory cell being an m-th memory cell from the third terminal in the second cell block,
wherein the control circuit controls voltages applied to the first word line and the second word line to cause the first cell block and the second cell block to output, to the logic circuit, the output voltage which is based on data stored in the first memory cell and the second memory cell and an output voltage which is based on data stored in the third memory cell and the fourth memory cell in a time-sharing manner.

4. The device according to claim 1, wherein the first terminal is coupled to a first bit line, and the third terminal is coupled to a second bit line.

5. The device according to claim 4, wherein when data is written to the first memory cell and the second memory cell,
the control circuit applies a first voltage to the first bit line, a second voltage to the second bit line, a pass voltage to a word line coupled to a memory cell in the first cell block other than the first memory cell and a memory cell in the second cell block other than the second memory cell, and a program voltage to the first word line.

6. The device according to claim 4, wherein the control circuit applies a first voltage to the first bit line, a second voltage to a second bit line, a read voltage to a memory cell in the first cell block other than the first memory cell and a memory cell in the second cell lock other than the second memory cell, and 0V to the first word line, to cause the first cell block and the second cell block to output, to the logic circuit, an output voltage based on data stored in the first memory cell and the second memory cell.

7. The device according to claim 1, wherein the logic circuit includes a transistor including a gate, and
the second terminal and the fourth terminal are coupled to the gate of the transistor.

8. The device according to claim 1, wherein the logic circuit includes a latch circuit including a first end and a second end, and
the second terminal is coupled to the first end, and the fourth terminal is coupled to the second end of the latch circuit.

9. The device according to claim 1, wherein the logic circuit includes a latch circuit and a reset circuit, the latch circuit including a first end and a second end, and
the second terminal is coupled to the first end of the latch circuit, and the reset circuit is coupled to the second end of the latch circuit.

10. The device according to claim 1, wherein the logic circuit is configurable circuit, and
data stored in the first memory cell and the second memory cell is context information of the logic circuit.

11. The device according to claim 1, wherein the device is a Field Programmable Gate Array (FPGA).

12. The device according to claim 1, wherein the memory cells are stacked above a semiconductor substrate.

13. A semiconductor device comprising:
a memory storing context information of a logic circuit; and
the logic circuit configurable based on the context information stored in the memory,
wherein the memory includes:
a first cell block coupled between a first terminal and a second terminal and including a plurality of memory cells coupled in series;
a second cell block coupled between a third terminal and a fourth terminal and including a plurality of memory cells coupled in series, the memory cells in the first cell block and the second cell block storing the context information, the logic circuit being coupled to the second terminal and the fourth terminal;
a first word line coupled to a first memory cell and a second memory cell, the first memory cell being an n-th memory cell from the first terminal in the first cell block, the second memory cell being an n-th memory cell from the third terminal in the second cell block; and
a control circuit configured to control a voltage applied to the first word line to cause the memory to output, to the logic circuit, an output voltage which is based on data stored in the first memory cell and the second memory cell

14. The device according to claim 13, wherein the first memory cell and the second memory cell store complementary data each other.

15. The device according to claim 13, wherein the memory further includes a second word line coupled to a third memory cell and a fourth memory cell, the third memory cell being an m-th memory cell from the first terminal in the first cell block, the fourth memory cell being an m-th memory cell from the third terminal in the second cell block, and
wherein the control circuit controls voltages applied to the first word line and the second word line to cause the memory to output, to the logic circuit, the output voltage which is based on data stored in the first memory cell and the second memory cell and an output voltage which is based on data stored in the third memory cell and the fourth memory cell in a time-sharing manner.
